(19) United States
(12) Patent Application Publication
(10) Pub. No.: US 2007/0147525 A1
(43) Pub. Date: Jun. 28, 2007

(54) Apparatus and method for controlling gain in an interference cancellation receiver of an OFDMA system

(76) Inventors: Yong-Chul Song, Seoul (KR); Young-Mo Gu, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 11/634,394

(22) Filed: Dec. 6, 2006

(30) Foreign Application Priority Data
Dec. 6, 2005 (KR) 2005-118371

(51) Int. Cl. H04K 1/10; H03D 1/04

(52) U.S. Cl. 375/260; 375/346

(57) ABSTRACT

A gain control apparatus of an interference cancellation receiver that performs interference cancellation in a frequency axis in an Orthogonal Frequency Division Multiple Access (OFDMA) system. A first signal power measurer measures first signal power of a received signal that was received from a base station and then underwent fast Fourier transform (FFT). A first range controller generates a first range control value for matching the first signal power to an operating point of the FFT-processed original signal. An FFT output buffer buffers the FFT-processed received signal. A second signal power measurer measures second signal power of a regenerated interference signal. A second range controller compares the first signal power with the second signal power, and generates a second range control value for controlling a gain of an output signal according to an operating point of a signal obtained by canceling the interference signal from the received signal output from the FFT output buffer.

### PRIORITY

This application claims the benefit under 35 U.S.C. §119(a) of an application entitled “Apparatus and Method for Controlling Gain in an Interference Cancellation Receiver of an OFDMA System” filed in the Korean Intellectual Property Office on Dec. 6, 2005 and assigned Serial No. 2005-118371, the entire contents of which are hereby incorporated by reference.

### BACKGROUND OF THE INVENTION

1. Field of the Invention

The present invention relates generally to a receiver of an Orthogonal Frequency Division Multiple Access (OFDMA) system employing an interference cancellation technique. More particularly, the present invention relates to a gain controller in a receiver of an OFDMA system employing an interference cancellation technique, and a gain control method for the same.

2. Description of the Related Art

In a general OFDMA system, in order to perform signal processing on a reduced level signal, that is, an interference-canceled signal, a receiver using an interference signal cancellation method capable of improving reception performance of the receiver by effectively canceling interference signals should operate over a wide operating domain without performance degradation. However, this causes an increase in complexity of the receiver.

In addition, if the receiver, like the general receiver, performs signal processing on the basis of an operating point (or reference point) Pref, performance degradation occurs for the interference-canceled signal, causing the performance improved by interference cancellation to re-degrade.

### SUMMARY OF THE INVENTION

It is an object of exemplary embodiments of the present invention to provide a gain control apparatus and method for preventing performance degradation and minimizing reception complexity in a receiver of an OFDMA system employing an interference cancellation technique.

It is another object of exemplary embodiments of the present invention to provide a gain control apparatus and method for optimizing a particular operating point Pref in a receiver of an OFDMA system employing an interference cancellation technique.

According to one aspect of the present invention, there is provided a gain control apparatus of an interference cancellation receiver that performs interference cancellation in a time axis in an Orthogonal Frequency Division Multiple Access (OFDMA) system. The gain control apparatus includes a buffer for buffering a signal received from a base station; a first signal power measurer for measuring a first signal power of the received signal output from the buffer; a second signal power measurer for measuring a second signal power of a regenerated interference signal; and a range controller for comparing the first signal power with the second signal power, and generating a range control value for matching power of a signal obtained by canceling the interference signal from the received signal to an operating point of a fast Fourier transformer (FFT).

According to another aspect of the present invention, there is provided a gain control method of an interference cancellation receiver that performs interference cancellation in a time axis in an Orthogonal Frequency Division Multiple Access (OFDMA) system. The gain control method includes buffering a signal received from a base station; measuring a first signal power of the buffered received signal; measuring a second signal power of a regenerated interference signal; comparing the first signal power with the second signal power, and generating a range control value for matching power of a signal obtained by canceling the interference signal from the received signal to an operating point of a fast Fourier transformer (FFT); and controlling a gain of the interference-canceled signal using the range control value.

According to another aspect of the present invention, there is provided a gain control apparatus of an interference cancellation receiver that performs interference cancellation in a frequency axis in an Orthogonal Frequency Division Multiple Access (OFDMA) system. The gain control apparatus includes a first signal power measurer for measuring a first signal power of a received signal that was received from a base station and then underwent fast Fourier transform (FFT); a first range controller for generating a first range control value for matching the first signal power to an operating point of the FFT-processed original signal; an FFT output buffer for buffering the FFT-processed received signal; a second signal power measurer for measuring a second signal power of a regenerated interference signal; and a second range controller for comparing the first signal power with the second signal power, and generating a second range control value for controlling a gain of an output signal according to an operating point of a signal obtained by canceling the interference signal from the received signal output from the FFT output buffer.

According to yet another aspect of the present invention, there is provided a gain control method of an interference cancellation receiver that performs interference cancellation in a frequency axis in an Orthogonal Frequency Division Multiple Access (OFDMA) system. The gain control method includes measuring a first signal power of a received signal that was received from a base station and then underwent fast Fourier transform (FFT); generating a first range control value for matching the first signal power to an operating point of the FFT-processed original signal; buffering the FFT-processed received signal; measuring a second signal power of a regenerated interference signal; comparing the first signal power with the second signal power, and generating a second range control value for controlling a gain of an output signal according to an operating point of a signal obtained by canceling the interference signal from the buffered received signal; and controlling a gain of the interference-canceled signal using the second range control value.

### BRIEF DESCRIPTION OF THE DRAWINGS

The above and other objects, features and advantages of the present invention will become more apparent from the following detailed description when taken in conjunction with the accompanying drawings in which:

FIG. 1A is a block diagram of an interference cancellation receiver in a frequency domain in an OFDMA system;

FIG. 1B is a block diagram of an interference cancellation receiver in a time domain in an OFDMA system;

FIG. 2 is a diagram illustrating a flow of an interference-canceled signal in the interference cancellation receiver;

FIG. 3A is a diagram illustrating a structure of a gain controller to which interference cancellation is applied in a time axis according to an exemplary embodiment of the present invention;

FIG. 3B is a diagram illustrating a structure of a gain controller to which interference cancellation is applied in a time axis according to another exemplary embodiment of the present invention;

FIGS. 4A and 4B are diagrams illustrating structures of gain controllers to which an interference cancellation technique is applied in a frequency axis according to an exemplary embodiment of the present invention;

FIG. 5 is a diagram illustrating a structure of a gain controller to which an interference cancellation technique is applied in a frequency axis according to another exemplary embodiment of the present invention;

FIGS. 6A to 6C are diagrams illustrating several exemplary range control values of a range controller in a gain controller according to an exemplary embodiment of the present invention;

FIGS. 7A and 7B are flowcharts illustrating a digital gain control method applied for interference cancellation in a time/frequency axis in an interference cancellation receiver according to an exemplary embodiment of the present invention; and

FIG. 8 is a flowchart illustrating a digital gain control method applied for interference cancellation in a time/frequency axis in an interference cancellation receiver according to another exemplary embodiment of the present invention.

Throughout the drawings, like reference numbers will be understood to refer to like elements, features and structures.

### DETAILED DESCRIPTION OF EXEMPLARY EMBODIMENTS

Exemplary embodiments of the present invention will now be described in detail with reference to the annexed drawings. It should be understood that the following description is merely exemplary, and it will be appreciated by those of ordinary skill in the art that changes and modifications to the embodiments described herein may be made without departing from the scope and spirit of the invention. Also, a detailed description of known functions and configurations incorporated herein has been omitted for clarity and conciseness.

A digital gain control apparatus (hereinafter referred to as a “digital gain controller”) used in an exemplary embodiment of the present invention includes a first signal power measurer for measuring power of an input signal, a second signal power measurer for measuring power of an interference signal, and a range controller for generating a range control value as a gain control value by comparing the signal output from the first signal power measurer with the signal output from the second signal power measurer.

The digital gain controller can be implemented in various forms according to a trade-off between the position of an interference canceller and the size and design complexity of a signal buffer.

The stages following the digital gain controller are designed such that the best performance occurs at a predetermined operating point (or reference point) Pref, thereby contributing to optimization of receiver complexity. An interference cancellation operation of the proposed receiver will now be described. During signal processing for estimation of an interference signal, the digital gain controller is controlled such that input signal power is located in the operating point Pref.

After the interference signal is estimated, pilots can be used for estimation of channel power of the interference signal. That is, the channel power of the interference signal can be found depending on the power of the pilots used for estimation of a channel for the interference signal.

Thereafter, if an interference signal is regenerated and subtracted from the original signal, the signal level decreases by the power of the interference signal, departing from the operating point. Due to the cancellation of the interference signal, a Carrier-to-Interference plus Noise Ratio (CINR) increases, but performance of the receiver may decrease because a signal range deviates from the designed operating point. Therefore, after the interference signal is canceled, the digital gain should be controlled once again to match the interference-canceled signal to the operating point of a signal processing block. Thereafter, if an interference signal is regenerated and subtracted from the original signal, the signal level decreases by the power of the interference signal, departing from the operating point. Accordingly, after the interference signal is canceled, the digital gain control should be performed once again.

With reference to the accompanying drawings, a detailed description will now be made of a structure and operation of a digital gain controller according to an exemplary embodiment of the present invention.

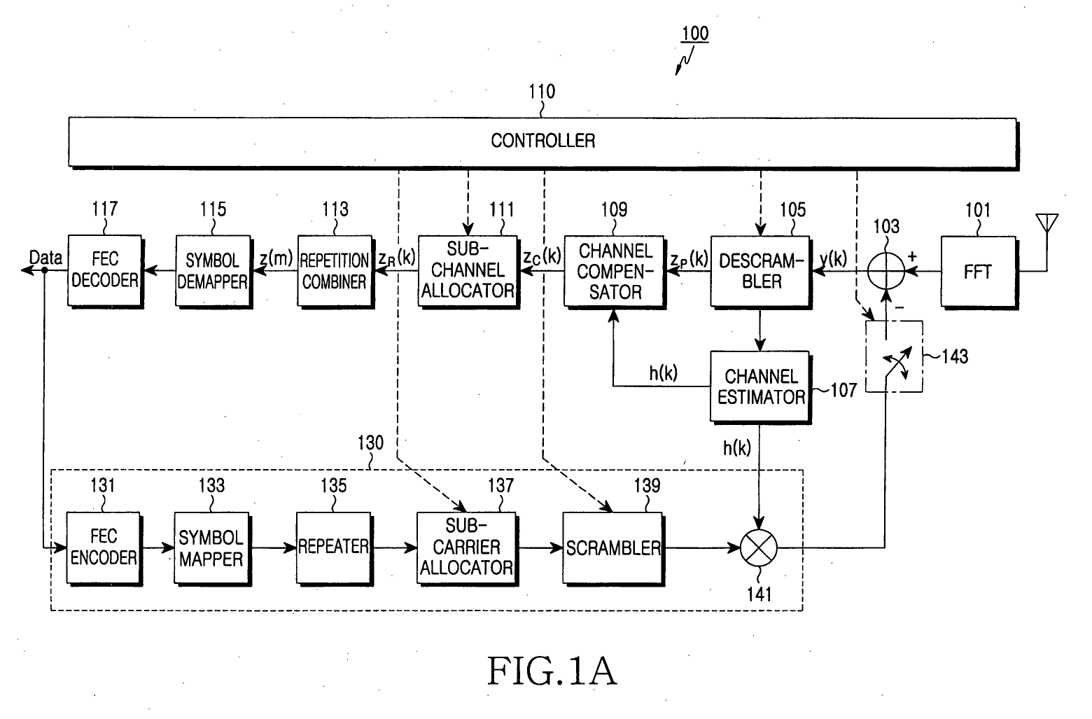

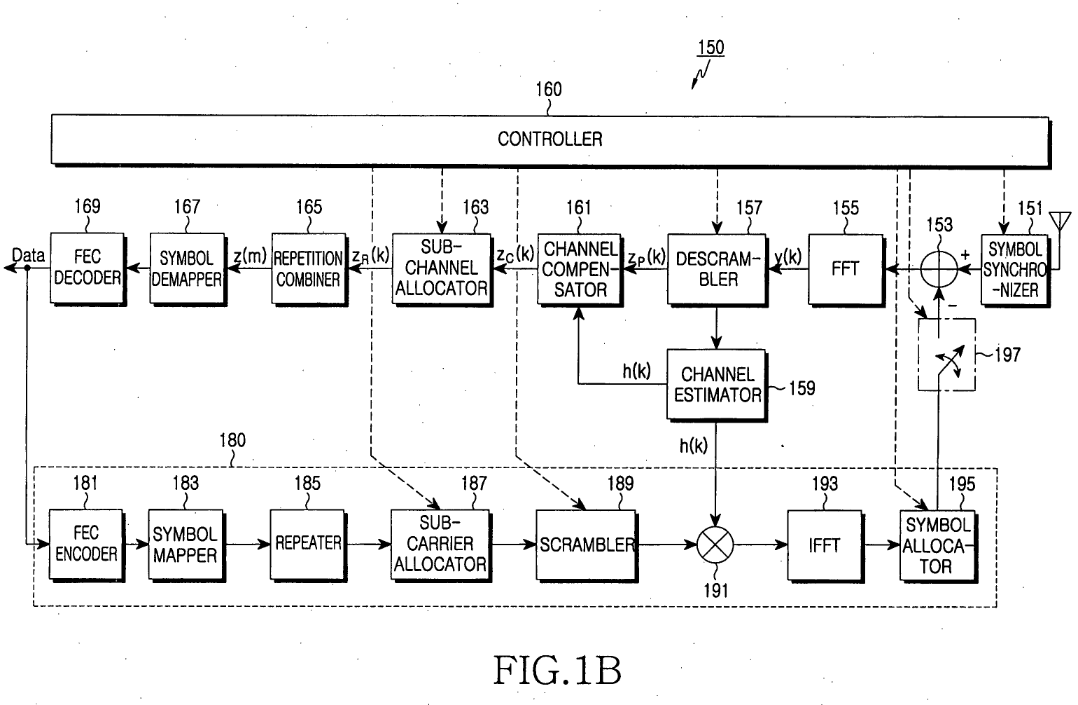

FIG. 1A is a block diagram of an interference cancellation receiver in a frequency domain in an OFDMA system. The interference cancellation receiver 100 has a structure for generating an interference signal for a received signal using Forward Error Correction (FEC), and subtracting the interference signal from the received signal, thereby improving its reception performance. That is, a method for decoding the downlink bursts of the interference signal will be referred to as an “FEC method.”

Referring to FIG. 1A, the interference cancellation receiver 100 includes a controller 110 for controlling each of the function blocks for the use of the FEC method, and an interference signal canceller 130 for regenerating an interference signal using the FEC method.

Because a receiving process (corresponding to reference numerals 101, 105, 109, 111, 113, 115 and 117) from a base station (BS) in service (known as a serving BS) is equal to the general receiving process, the following description will be focused on the controller 110 and the interference signal canceller 130. The interference cancellation receiver 100 includes the interference signal canceller 130 for regenerating a received interference signal, a subtractor 103 for subtracting the signal regenerated by the interference signal canceller 130 from the signal received from the serving BS under the control of the controller 130, a switch 143 for switching the subtraction, and the controller 110 for controlling the use the regenerated interference signal from the interference signal canceller 130 and controlling each of the function blocks, in addition to the general reception blocks. Herein, the phrase “regenerating an interference signal” means generating the same signal as the interference signal from a transmitter of the neighbor BS that generated the interference signal.

The interference cancellation receiver 100 will now be described in more detail. To detect an interference signal, the controller 110 first detects an interference signal using an Identifier (ID) of a neighbor BS from which an interference signal is received. Herein, the interference signal is detected by a CINR measurer (not shown). The controller 110 measures interference signals from neighbor BSs using the CINR measurer, and controls the interference signal canceller 130 and the switch 143 if the measured interference signals satisfy a predetermined condition.

If the interference signals from the neighbor BSs are greater than or equal to a predetermined threshold, the controller 110 receives the interference signals from the corresponding BSs. The method for detecting an interference signal uses the same scheme as that of the general OFDMA receiver. That is, the received signal is detected through a descrambler 105, a channel estimator 107, a channel compensator 109, a sub-channel allocator 111, a repetition combiner 113, a symbol demapper 115, and an FEC decoder 117.

The interference signal canceller 130 regenerates the interference signal transmitted over a channel using the interference signal detected from the received signal. The interference signals are regenerated in the generated order in the general OFDMA transmitter. Therefore, the interference signal canceller 130 includes an FEC encoder 131, a symbol mapper 133, a repeater 135, a sub-carrier allocator 137, a scrambler 139, and a multiplier 141. That is, the method for generating interference signals is executed through FEC encoding, symbol mapping, repetition coding, sub-carrier permutation and scrambling processes.

The multiplier 141 multiplies the result of the channel estimation made by the channel estimator 107 by the generated interference signal. In this way, the interference signal received over a channel is obtained. That is, finally, a pure interference-canceled signal can be obtained by subtracting the regenerated interference signal from the received signal. The interference cancellation receiver 100 detects a self signal from the interference-canceled received signal using a BS ID of a serving cell, like the OFDMA reception scheme. The controller 110 controls the flow of such signals. That is, the interference cancellation receiver 100 provides a BS ID for the interference signal to the scrambler 139, the descrambler 105, the sub-carrier allocator 137, and the sub-channel allocator 111, during detection or regeneration of the interference signal, and provides its BS ID to the above blocks during detection of the self signal.

FIG. 1B is a block diagram of an interference cancellation receiver in a time domain in an OFDMA system.

Referring to FIG. 1B, the interference cancellation receiver 150 includes a controller 160 for controlling each of the function blocks for the use of the FEC method according to an exemplary embodiment of the present invention, and an interference signal canceller 180 for regenerating an interference signal using the FEC method.

As done in FIG. 1A, the description will be focused on the controller 160 and the interference signal canceller 180 according to an exemplary embodiment of the present invention. The interference cancellation receiver 150 includes a symbol synchronizer 151 for performing independent symbol synchronization acquisition for each interference signal, the interference signal canceller 180 for regenerating a received interference signal, a subtractor 153 for subtracting the signal regenerated by the interference signal canceller 180 from the signal of the serving BS, a switch 197 for switching the subtraction, and the controller 160 for controlling the use of the signal regenerated by the interference signal canceller 180 and controlling each of the function blocks, in addition to the general reception blocks.

An operation of the interference cancellation receiver 150 will now be described. To detect an interference signal, the controller 160 first detects an interference signal using an ID of a neighbor BS from which an interference signal is received. Herein, the interference signal is detected by a CINR measurer (not shown). The controller 160 measures interference signals from neighbor BSs using the CINR measurer, and controls the interference signal canceller 180 and the switch 197 if the measured interference signals satisfy a predetermined condition. The function blocks in the block drawn by a dotted line in FIG. 1B are under the control of the controller 160.

If the interference signals from the neighbor BSs are greater than or equal to a predetermined threshold, the controller 160 acquires independent symbol synchronization for the interference signals from the corresponding BSs using the symbol synchronizer 151. Thereafter, a Fast Fourier Transformer (FFT) 155 receives the interference signals from the corresponding BSs for which the symbol synchronization is acquired. As described in FIG. 1A, the method for detecting an interference signal uses the same scheme as that of the general OFDMA receiver. That is, the received signal is detected through a descrambler 157, a channel estimator 159, a channel compensator 161, a sub-channel allocator 163, a repetition combiner 165, a symbol demapper 167, and an FEC decoder 169.

The interference signal canceller 180 regenerates the interference signal transmitted over a channel, using the interference signal detected from the received signal. The phrase “regenerating an interference signal” means generating the same signal as the transmitted interference signal. As described in FIG. 1A, the interference signals are regenerated in the generated order in the general OFDMA transmitter. Therefore, the interference signal canceller 180 includes an FEC encoder 181, a symbol mapper 183, a repeater 185, a sub-carrier allocator 187, a scrambler 189, a multiplier 191, an Inverse Fast Fourier Transformer (IFFT) 193 and a symbol allocator 195. That is, the method for generating interference signals is performed through FEC encoding, symbol mapping, repetition coding, sub-carrier permutation and scrambling processes. Thereafter, the multiplier 191 multiplies the result of the channel estimation made by the channel estimator 159 by the generated interference signal.

Herein, because the interference signal is subtracted in the time domain, the interference cancellation receiver 150 performs an IFFT process to transform the regenerated interference signal into a time-domain signal. The transformed time-domain interference signal aligns the time axis of the generated interference signal through the symbol allocator 195.

The symbol allocator 195 stores the generated interference signals in a buffer included therein in units of symbols. Thereafter, using the fact that the interference signals are stored in symbols, the symbol allocator 195 aligns the time axis of the next applied interference signal and the interference signal generated in the time domain corresponding to a symbol interval of the serving BS.

An interference-canceled signal can be obtained by subtracting the interference signal output from the symbol allocator 195 from the next signal of the serving BS. The interference cancellation receiver 150 detects a self signal from the interference-canceled signal using a BS ID of the serving cell, like the existing OFDMA reception scheme. The controller 160 controls the flow of such signals. That is, the interference cancellation receiver 150 provides a BS ID for the interference signal to the scrambler 189, the descrambler 157, the sub-carrier allocator 187, and the sub-channel allocator 163, during detection or regeneration of the interference signal, and provides its BS ID to the above blocks during detection of the self signal.

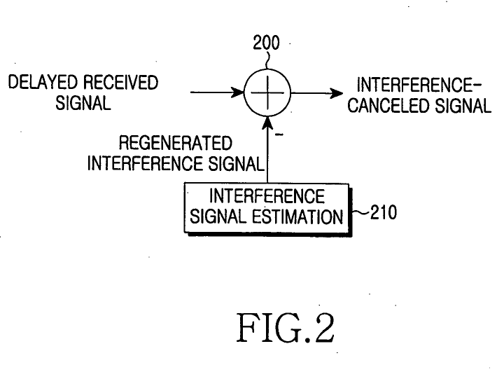

The interference cancellation technique in the OFDMA system is a method for extracting an interference signal component from the received signal, canceling the extracted interference component from the received signal, and then performing signal processing on the interference-canceled signal, thereby improving performance of the receiver. This method is well expressed in FIG. 2.

FIG. 2 is a diagram illustrating the flow of only the interference-canceled signal in the interference cancellation receiver.

Referring to FIG. 2, after a subtractor 200 cancels (subtracts) a regenerated interference signal provided from an interference signal estimator 210 from a delayed received signal, the signal level decreases. The decreased signal level can be adjusted by applying a gain controller according to an exemplary embodiment of the present invention to the interference cancellation receiver. This process will be described in detail hereinbelow.

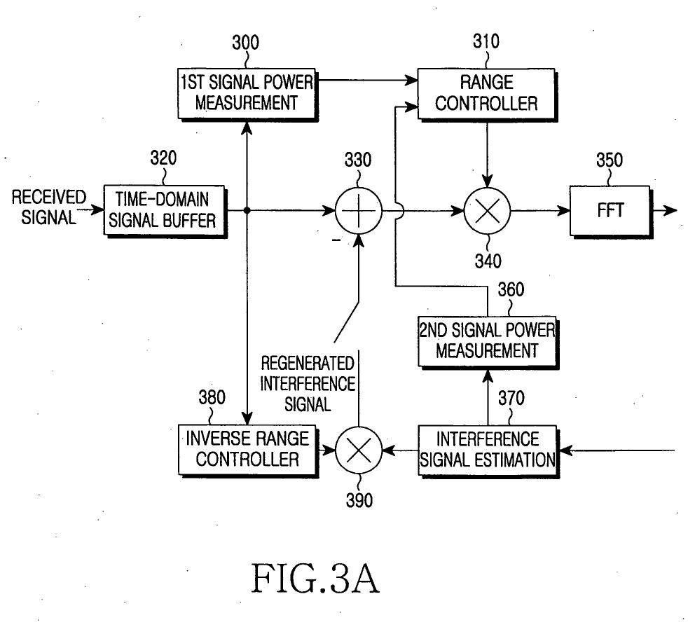

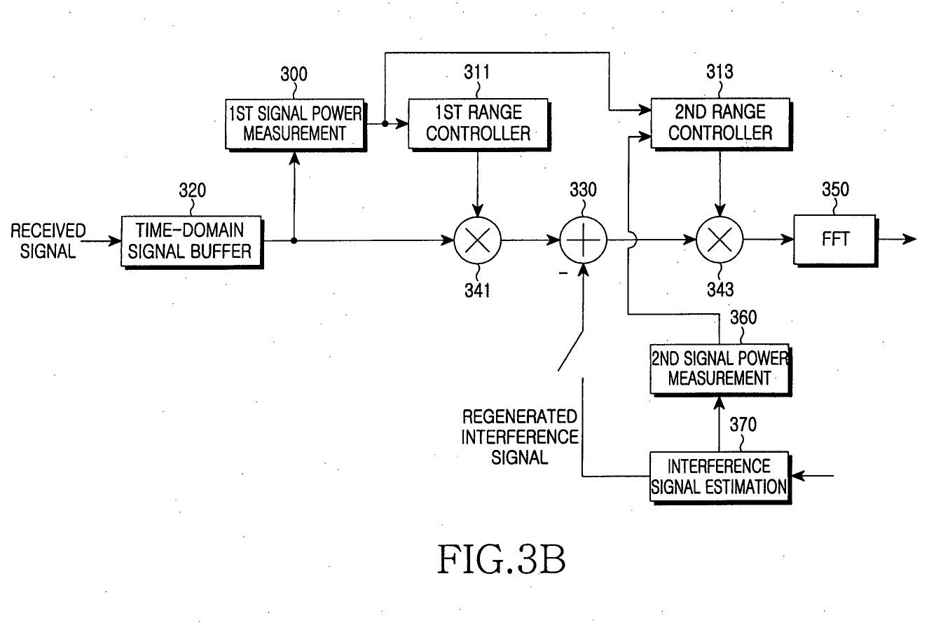

FIG. 3A is a diagram illustrating a structure of a gain controller to which interference cancellation is applied in a time axis according to an exemplary embodiment of the present invention.

Referring to FIG. 3A, the gain controller in the time axis includes a first signal power measurer 300, a range controller 310, an inverse range controller 380, a time-domain signal buffer 320, multipliers 340 and 390, and a second signal power measurer 360, and is combined between an interference signal estimator 370, a subtractor 330 and an FFT 350 of the interference cancellation receiver.

A gain readjustment block for changing signal power of the regenerated interference signal to the original signal power range includes an inverse range controller 380 and a multiplier 390. Because the interference signal has the channel power obtained from the power at the operating point, there is a need to readjust the gain to change signal power of the interference signal back to the original signal power range.

The time-domain signal buffer 320 is provided to contain the time-axis signal in order to apply the interference cancellation technique, and a required size of the time-domain signal buffer 320 corresponds to the delay required for estimation of the interference signal. Therefore, in the operation performed when the received signal passes through the time-domain signal buffer 320 for estimation of the interference signal, digital gain control is performed only with the power of the original signal. That is, the power estimated by the interference signal estimator 370 is ‘0’.

Thereafter, if signal processing on the interference signal is completed through the FFT 350 and the interference signal is regenerated, interference signal cancellation is performed again on the corresponding OFDM symbol by the subtractor 330.

In the interference cancellation process, the gain should be inversely readjusted according to the digital gain controlled by the original signal. If power of the original signal is denoted by P and power of the interference signal is denoted by Pi, power of the interference-canceled signal after passing through the subtractor 330 is (P−Pi). Therefore, the power of the interference-canceled signal deviates from an operating point by Pi on the basis of an input to the FFT 350.

This is readjusted by the digital gain controller and can be matched to the operating point where the optimal performance can be obtained. That is, the range controller 310 calculates a gain control value depending on the measured signal power received from the first signal power measurer 300 via the time-domain signal buffer 320 and the measured signal power received from the second signal power measurer 360 via the interference signal estimator 370. The gain control value is multiplied by the interference-canceled signal at the multiplier 340, thereby controlling the gain. Here, for the power of the original signal, as it is a value in the time axis, the power measured from the preamble is used.

FIG. 3B is a diagram illustrating a structure of a gain controller to which interference cancellation is applied in a time axis according to another embodiment of the present invention.

Referring to FIG. 3B, the gain controller has a structure of separately arranging gain controllers before and after a subtractor 330, which is an interference signal cancellation block, without using a gain readjustment block for the interference signal during interference cancellation.

In this case, the gain controller before the subtractor 330 matches an operating point Pref for signal processing through a first signal power measurer 300, a first range controller 311, and a multiplier 341, using only the power P of the original signal. The gain controller after the subtractor 330, as described in FIG. 3A, has a structure of matching an operating point Pref using power (Pref−Pi) of the interference-canceled signal according to operation of a second signal power measurer 360, a second range controller 313, and a multiplier 343. In this structure, signal power before the subtractor 330 is Pref, and power of the interference signal regenerated based on this is Pi.

Such digital gain control can maintain power of the input node of the FFT 350 at the constant operating point for both before and after the interference cancellation.

Basically, OFDMA may not send not only the data but also the pilot in the non-allocated time-frequency domain considering the interference problem. That is, in the time axis, there is no signal that can be a reference in calculating channel power, except for the preamble. Because the part that should be compensated by the actual digital gain control is a change in channel power, power estimation and adjustment in the frequency axis can increase the accuracy, compared with power estimation and adjustment in the time axis.

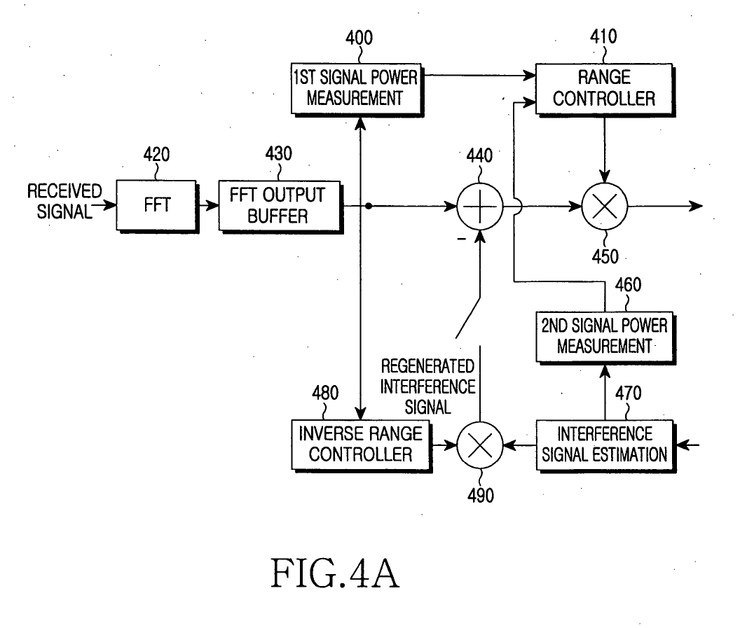

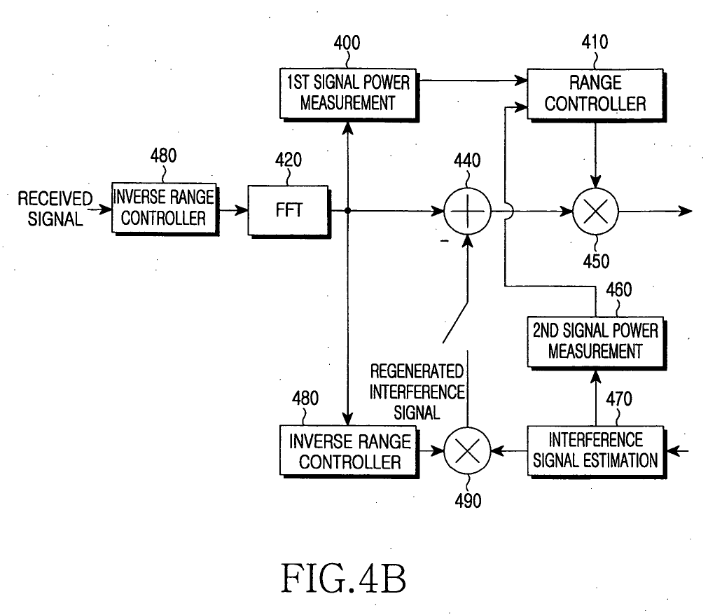

FIGS. 4A and 4B are diagrams illustrating structures of gain controllers to which an interference cancellation technique is applied in a frequency axis according to an exemplary embodiment of the present invention.

Referring to FIG. 4A, the gain controller in the frequency axis includes a first signal power measurer 400, a range controller 410, an inverse range controller 480, an FFT output buffer 430, multipliers 450 and 490, and a second signal power measurer 460, and is applied between an interference signal estimator 470, a subtractor 440, and an FFT 420 of an interference cancellation receiver.

A gain readjustment block for changing signal power of the interference signal to the original signal power range includes an inverse range controller 480 and a multiplier 490. Because the interference signal has the channel power obtained from the power at the operating point, there is a need to readjust the gain to change signal power of the interference signal back to the original signal power range.

Referring to FIG. 4A, the gain controller in the frequency axis includes the FFT output buffer 430 following the FFT 420. This is a scheme for separately implementing digital gain controllers in a signal path and an interference signal path, and has a structure that cannot store the required number bits by simply adjusting the FFT output to the operating point. That is, because the digital gain controller should be located after the interference cancellation block, all of the FFT output bits should be stored in the FFT output buffer 430.

Referring to FIG. 4B, the gain controller, unlike the gain controller of FIG. 4A, has a structure in which a received signal undergoes digital gain control after passing through the FFT 420 via an FFT input buffer 490. Because the number of FFT output bits is generally greater than the number of FFT input bits, it is effective to arrange the FFT input buffer 490 before the FFT 420 and store the FFT input therein, in reducing the buffer size in this structure. In this case, however, the FFT process should be performed two times for estimation and cancellation of the interference signal.

During estimation of the interference signal, the structure of FIG. 4A estimates power of the original signal using a pilot of the FFT output buffer 430 and performs gain control. That is, the power estimated by the interference signal estimator 470 is ‘0’. Thereafter, if the interference signal is estimated and canceled, the gain is readjusted to match the signal of the FFT output buffer 430 to the signal range. In other words, because in terms of the signal power, the interference signal is matched to the operating point Pref and the signal of the FFT output buffer 430 is matched to the power P, there is a need to readjust the gain back to the signal range of the FFT output buffer 430.

Because the actual interference signal is a signal regenerated based on the operating point Pref, the gain is readjusted by P/Pref back to the signal regenerated based on the power P. As a result, the regenerated interference signal has the power Pi. That is, the interference signal component in the signal stored in the FFT output buffer 430 corresponds to this. The power (P−Pi) after the interference signal is canceled again after the interference cancellation becomes the operating point Pref, based on which gain adjusted signal processing is performed. In this case, a range control value output from the range controller 410 is obtained by subtracting interference signal power Pi from received signal power P and dividing reference power Pref indicating an operating point by the subtracted value (Pref/(P−Pi)).

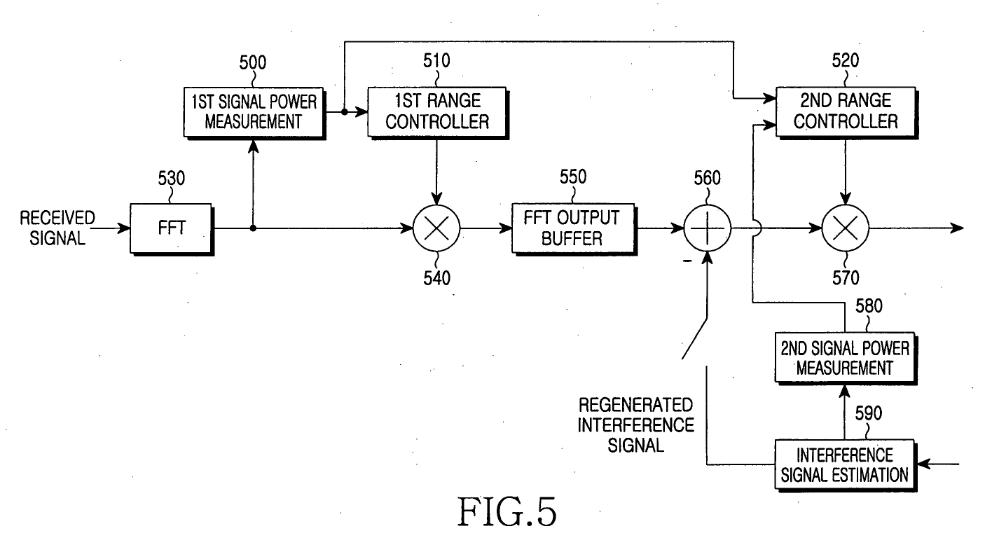

FIG. 5 is a diagram illustrating a structure of a gain controller to which an interference cancellation technique is applied in a frequency axis according to another embodiment of the present invention.

Referring to FIG. 5, the gain controller in the frequency axis has a structure of arranging both digital gain controllers in the signal path, matching an FFT output of a received signal to an operating point with a first gain controller, storing only a required number of bits, and after cancellation of the interference signal, matching the interference-canceled signal back to the operating point with a second gain controller.

In this case, the size of the FFT output buffer, which is the problem of the structure of FIG. 4A, can be optimized, contributing to optimization of complexity of the receiver (or terminal). That is, the gain controller including a first signal power measurer 500 and a first range controller 510 at the FFT output stores signals in an FFT output buffer 550 after matching the operating point to the power P of the signal, and the gain controller including a second signal power measurer 580 and a second range controller 520 after a subtractor 560 for interference cancellation performsgain adjusted signal processing for matching the power (Pref−Pi) of the interference-canceled signal to the power of the operating point Pref In this case, a range control value output from the second range controller 520 is obtained by subtracting interference signal power Pi from reference power Pref and dividing the reference power Pref indicating an operating point by the subtracted value (Pref/(Pref−Pi)).

The structure of FIG. 5 can divide an operation of the range controllers into an operation during interference signal estimation and an operation after interference signal estimation. The gain controller controls a gain of an FFT output for the original signal by Pref/P, and stores the signal in the FFT output buffer 550. The gain controller starts interference signal estimation using the values of the FFT output buffer 550. At this time, the gain controller following the subtractor 560, which is an interference cancellation block, does not perform gain control. That is, the power of the signal that passes through the above block during interference signal estimation is matched to the Pref.

After the interference signal is estimated, the estimated interference signal is canceled from the signal of the FFT output buffer. At this point, the signal of the FFT output buffer is matched to the Pref, and the regenerated interference signal is made based on the Pref and its power is Pi. Therefore, the power of the interference-canceled signal becomes (Pref−Pi). This is matched to the operating point Pref, based on which signal processing is made.

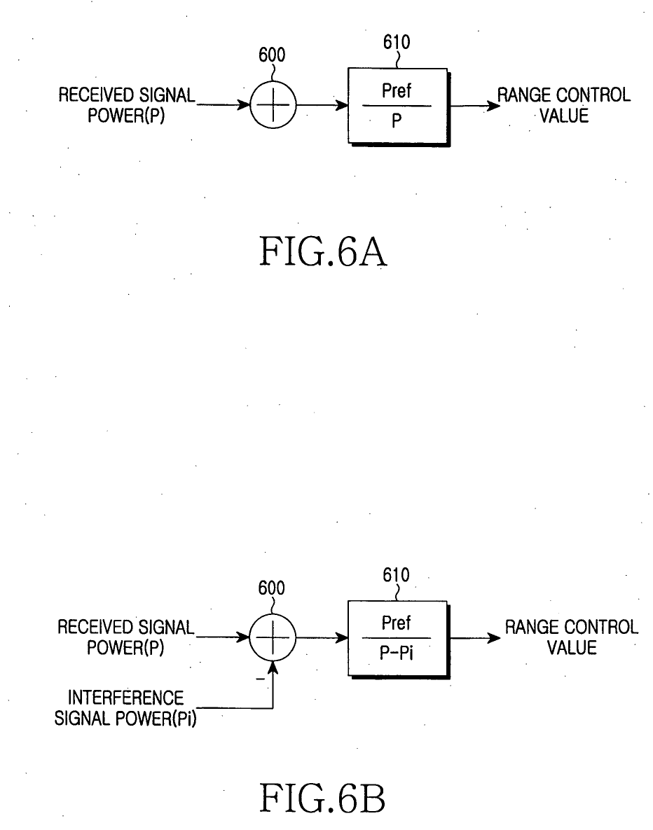

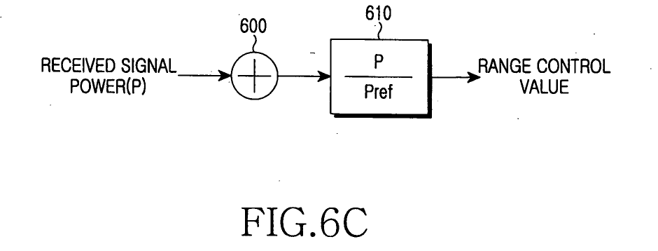

FIGS. 6A to 6C are diagrams illustrating several exemplary range control values of a range controller in a gain controller according to an exemplary embodiment of the present invention.

Referring to FIGS. 6A to 6C, the range controller includes a subtractor 600 and a range control value calculator 610. In FIG. 6A, the range controller for the original received signal outputs a ratio (or gain) Pref/P of operating point power Pref to received signal power P, and multiplies the received signal by the gain Pref/P. The gain Pref/P is out from the first range controller 311, 510 shown in FIGS. 3B and 5.

FIG. 6B illustrates a structure of a range controller for an interference-canceled signal. The range controller for an interference-canceled signal is basically equal to those of FIGS. 6A and 6C in structure, but is different in function. A digital gain control value after interference cancellation is obtained by subtracting interference signal power Pi from received signal power P and dividing reference power Pref indicating an operating point by the subtracted value (Pref/(P−Pi)), and if the digital gain control value is multiplied by the interference-canceled signal, the signal is maintained at the operating point Pref. In this case, the range control value(or gain) after interference cancellation is obtained as the value (Pref/(P−Pi)). The gain Pref/(P−Pi) can be applied to the range controller 310, 410 shown in FIGS. 3A, 4A and 4B as well as the second range controller 313, 520 shown in FIGS. 3B, 5. Furthermore, the second range controller 313, 520 is preferably operated using the power of the operating point Pref rather than the received signal power. In this case, the range control value output from the second range controller 313, 520 is obtained as (Pref/(Pref−Pi)). and if the digital gain control value is multiplied by the interference-canceled signal, the signal is maintained at the operating point Pref.

Finally, FIG. 6C illustrates a structure of an inverse range controller. The inverse range controller is also basically equal to those of FIGS. 6A and 6B in structure, but is different in function. Because the interference signal has the channel power obtained at operating point power, a gain readjustment block for changing signal power of the interference signal to the original signal power range needs to readjust a gain for P/Pref in order to change signal power of the interference signal to the original signal power range.

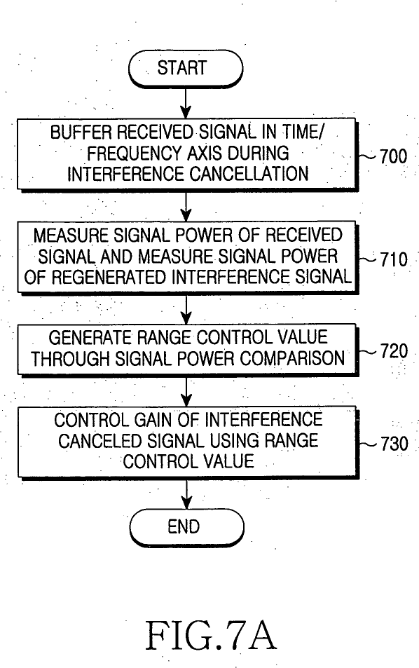

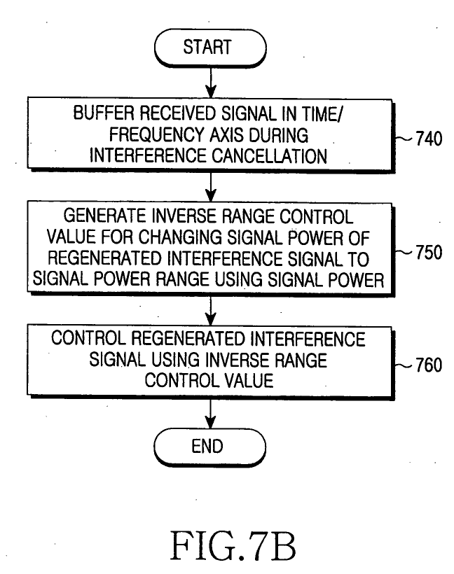

FIGS. 7A and 7B are flowcharts illustrating a digital gain control method applied for interference cancellation in a time/frequency axis in an interference cancellation OFDMA receiver according to an exemplary embodiment of the present invention. The methods of FIGS. 7A and 7B can be applied to the gain controller described in FIGS. 3A, 4A and 4B.

Referring to FIG. 7A, in step 700, a time-domain signal buffer, an FFT input buffer, or an FFT output buffer buffers a signal received from a BS during interference cancellation. In step 710, a first signal power measurer measures first signal power by measuring signal power of the buffered received signal, and a second signal power measurer measures second signal power by measuring signal power of a regenerated interference signal.

In step 720, a range controller compares the signal power of the received signal with the signal power of the regenerated interference signal, and controls a range in which a range control value is generated. In step 730, a first multiplier controls a gain of the regenerated interference signal using the range control value.

Referring to FIG. 7B, in step 740, a time-domain signal buffer, an FFT input buffer, or an FFT output buffer buffers a signal received from a BS during interference cancellation. In step 750, an inverse range controller generates an inverse range control value for changing signal power of the regenerated interference signal to the original signal power range using signal power of the buffered received signal. In step 760, a second multiplier controls a gain of the regenerated interference signal using the inverse range control value.

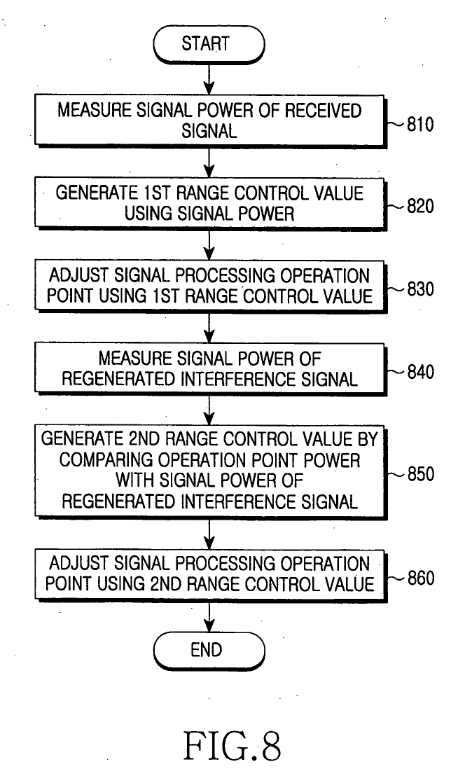

FIG. 8 is a flowchart illustrating a digital gain control method applied for interference cancellation in a time/frequency axis in an interference cancellation OFDMA receiver according to another embodiment of the present invention. The method of FIG. 8 can be applied to the gain controller described in FIGS. 3B and 5.

Referring to FIG. 8, in step 810, a first signal power measurer measures first signal power by measuring signal power of a buffered received signal. In step 820, a first range controller generates a first range control value using the first signal power. In step 830, a first multiplier controls an operating point for signal processing using the first range control value.

In step 840, a second signal power measurer measures second signal power by measuring signal power of a regenerated interference signal. In step 850, a second range controller compares the operating point power with the second signal power, and generates a second range control value. In step 860, a second multiplier controls an operating point for signal processing using the second range control value.

As can be understood from the foregoing description, embodiments of the present invention provide a digital gain controller for minimizing an increase in complexity of a receiver in performing signal processing without degradation of the performance improved by interference cancellation, and a method therefor.

In addition, embodiments of the present invention add a digital gain controller to an interference canceller thereby to optimize design of a signal processor to a particular operating pint Pref.

Further, embodiments of the present invention can obtain a constant performance gain given by interference cancellation without an increase in complexity of a receiver except for addition of a digital gain controller.

Moreover, in order to increase terminal (or receiver) performance by canceling interference signals from neighbor cells in designing a receiver for an OFDMA system, embodiments of the present invention design the constant operating point Pref through digital gain control regardless of whether design of a post-FFT stage comes before or after interference cancellation.

Besides, embodiments of the present invention facilitate optimal design of an OFDMA receiver in terms of the complexity.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A gain control apparatus of an interference cancellation receiver that performs interference cancellation in a time axis in an Orthogonal Frequency Division Multiple Access (OFDMA) system, comprising:
a buffer for buffering a signal received from a base station;
a first signal power measurer for measuring a first signal power of the received signal output from the buffer;
a second signal power measurer for measuring a second signal power of a regenerated interference signal; and
a range controller for comparing the first signal power with the second signal power, and generating a range control value for matching power of a signal obtained by canceling the interference signal from the received signal to an operating point of a fast Fourier transformer (FFT).

2. The gain control apparatus of claim 1, wherein the range controller generates the range control value (Pref/(P−Pi)) by dividing the signal power (Pref) of the operating point by signal power (P−Pi) determined by subtracting the second signal power (Pi) from the first signal power (P).

3. The gain control apparatus of claim 1, further comprising an inverse range controller for generating an inverse range control value for changing the second signal power of the regenerated interference signal to an original signal power range using the first signal power.

4. The gain control apparatus of claim 3, wherein the inverse range control value (P/Pref) is determined by dividing the first signal power (P) by signal power (Pref) obtained at the operating point.

5. The gain control apparatus of claim 1, wherein the first signal power is measured from a preamble of an OFDM signal.

6. A gain control method of an interference cancellation receiver that performs interference cancellation in a time axis in an Orthogonal Frequency Division Multiple Access (OFDMA) system, comprising the steps of:
buffering a signal received from a base station;
measuring a first signal power of the buffered received signal;
measuring a second signal power of a regenerated interference signal;
comparing the first signal power with the second signal power, and generating a range control value for matching power of a signal obtained by canceling the interference signal from the received signal to an operating point of a fast Fourier transformer (FFT); and
controlling a gain of the interference-canceled signal using the range control value.

7. The gain control method of claim 6, wherein the range control value (Pref/(P−Pi)) is generated by dividing the signal power (Pref) of the operating point by signal power (P−Pi) determined by subtracting the second signal power (Pi) from the first signal power (P).

8. The gain control method of claim 6, further comprising the steps of:
generating an inverse range control value for changing the second signal power to an original signal power range using the first signal power; and
multiplying the regenerated interference signal by the inverse range control value.

9. The gain control method of claim 8, wherein the inverse range control value (P/Pref) is determined by dividing the first signal power (P) by signal power (Pref) obtained at the operating point.

10. The gain control method of claim 6, wherein the first signal power is measured from a preamble of an OFDM signal.

11. A gain control apparatus of an interference cancellation receiver that performs interference cancellation in a time axis in an Orthogonal Frequency Division Multiple Access (OFDMA) system, comprising:
a buffer for buffering a signal received from a base station;
a first signal power measurer for measuring a first signal power of the received signal output from the buffer;
a first range controller for generating a first range control value for matching the first signal power to an operating point of a fast Fourier transformer (FFT);
a second signal power measurer for measuring a second signal power of a regenerated interference signal; and
a second range controller for comparing power of the operating point with the second signal power, and generating a second range control value for matching power of a signal determined by canceling the interference signal from the received signal to the operating point.

12. The gain control apparatus of claim 11, wherein the first range controller generates the first range control value (Pref/P) by dividing power (Pref) of the operating point by the first signal power (P).

13. The gain control apparatus of claim 12, wherein the second range controller generates the second range control value (Pref/(Pref−Pi)) by dividing the signal power (Pref) of the operating point by signal power (Pref−Pi) determined by subtracting the second signal power (Pi) from the signal power (Pref) of the operating point.

14. A gain control method of an interference cancellation receiver that performs interference cancellation in a time axis in an Orthogonal Frequency Division Multiple Access (OFDMA) system, comprising the steps of:
buffering a signal received from a base station;
measuring a first signal power of the buffered received signal;
generating a first range control value for matching the first signal power to an operating point of a fast Fourier transformer (FFT);
measuring a second signal power of a regenerated interference signal;
comparing power of the operating point with the second signal power, and generating a second range control value for matching power of a signal determined by canceling the interference signal from the received signal to the operating point; and
controlling a gain of the interference-canceled signal using the second range control value.

15. The gain control method of claim 14, wherein the first range control value (Pref/P) is generated by dividing power (Pref) of the operating point by the first signal power (P).

16. The gain control method of claim 15, wherein the second range control value (Pref/(Pref−Pi)) is generated by dividing the signal power (Pref) of the operating point by signal power (Pref−Pi) determined by subtracting the second signal power (Pi) from the signal power (Pref) of the operating point.

17. A gain control apparatus of an interference cancellation receiver that performs interference cancellation in a frequency axis in an Orthogonal Frequency Division Multiple Access (OFDMA) system, comprising:
a fast Fourier transformer (FFT) output buffer for buffering a received signal that was received from a base station and then underwent fast Fourier transform (FFT);
a first signal power measurer for measuring a first signal power of the received signal output from the FFT output buffer;
a second signal power measurer for measuring a second signal power of a regenerated interference signal; and
a range controller for comparing the first signal power with the second signal power, and generating a range control value for matching power of a signal obtained by canceling the interference signal from the received signal to an operating point.

18. The gain control apparatus of claim 17, wherein the range controller generates the range control value (Pref/(P−Pi)) by dividing signal power (Pref) of the operating point by signal power (P−Pi) determined by subtracting the second signal power (Pi) from the first signal power (P).

19. The gain control apparatus of claim 17, further comprising an inverse range controller for generating an inverse range control value for matching the second signal power of the regenerated interference signal to a signal power range of the FFT output buffer using the first signal power.

20. The gain control apparatus of claim 19, wherein the inverse range control value (P/Pref) is determined by dividing signal power of the FFT output buffer by signal power (Pref) obtained at the operating point.

21. The gain control apparatus of claim 17, wherein the first signal power is measured from a pilot signal.

22. A gain control apparatus of an interference cancellation receiver that performs interference cancellation in a frequency axis in an Orthogonal Frequency Division Multiple Access (OFDMA) system, comprising:
a fast Fourier transformer (FFT) input buffer for buffering a received signal that was received from a base station but has not yet undergone fast Fourier transform (FFT);
a first signal power measurer for measuring first signal power of the received signal that has been output from the FFT input buffer and then undergone FFT;
a second signal power measurer for measuring second signal power of a regenerated interference signal; and
a range controller for comparing the first signal power with the second signal power, and generating a range control value for matching power of a signal obtained by canceling the interference signal from the FFT-processed received signal to an operating point.

23. A gain control method of an interference cancellation receiver that performs interference cancellation in a frequency axis in an Orthogonal Frequency Division Multiple Access (OFDMA) system, comprising the steps of:
buffering a received signal that was received from a base station and then underwent fast Fourier transform (FFT);
measuring a first signal power of the buffered received signal;
measuring a second signal power of a regenerated interference signal;
comparing the first signal power with the second signal power, and generating a range control value for matching power of a signal obtained by canceling the interference signal from the received signal to an operating point; and
controlling a gain of the interference-canceled signal using the range control value.

24. The gain control method of claim 23, wherein the range control value (Pref/(P−Pi)) is generated by dividing signal power (Pref) of the operating point by signal power (P−Pi) determined by subtracting the second signal power (Pi) from the first signal power (P).

25. The gain control method of claim 23, further comprising the step of generating an inverse range control value for matching the second signal power of the regenerated interference signal to the buffered original signal power range using the first signal power.

26. The gain control method of claim 23, wherein the inverse range control value (P/Pref) is determined by dividing the buffered original signal power (P) by signal power (Pref) obtained at the operating point.

27. The gain control method of claim 23, wherein the first signal power is measured from a pilot signal.

28. A gain control method of an interference cancellation receiver that performs interference cancellation in a frequency axis in an Orthogonal Frequency Division Multiple Access (OFDMA) system, comprising the steps of:
buffering a received signal that was received from a base station but has not yet undergone fast Fourier transform (FFT);
measuring a first signal power of the buffered received signal that has undergone FFT;
measuring a second signal power of a regenerated interference signal;
comparing the first signal power with the second signal power, and generating a range control value for matching power of a signal obtained by canceling the interference signal from the FFT-processed received signal to an operating point; and
controlling a gain of the interference-canceled signal using the range control value.

29. A gain control apparatus of an interference cancellation receiver that performs interference cancellation in a frequency axis in an Orthogonal Frequency Division Multiple Access (OFDMA) system, comprising:
a first signal power measurer for measuring a first signal power of a received signal that was received from a base station and then underwent fast Fourier transform (FFT);
a first range controller for generating a first range control value for matching the first signal power to an operating point of the FFT-processed original signal;
an FFT output buffer for buffering the FFT-processed received signal;
a second signal power measurer for measuring a second signal power of a regenerated interference signal; and
a second range controller for comparing the first signal power with the second signal power, and generating a second range control value for controlling a gain of an output signal according to an operating point of a signal obtained by canceling the interference signal from the received signal output from the FFT output buffer.

30. The gain control apparatus of claim 29, wherein the first range controller generates the first range control value (Pref/P) by dividing power (Pref) of the operating point by the first signal power (P).

31. The gain control apparatus of claim 29, wherein the second range controller generates the second range control value (Pref/(Pref−Pi)) by dividing the signal power (Pref) of the operating point by signal power (Pref−Pi) determined by subtracting the second signal power (Pi) from the signal power (Pref) of the operating point.

32. A gain control method of an interference cancellation receiver that performs interference cancellation in a frequency axis in an Orthogonal Frequency Division Multiple Access (OFDMA) system, comprising the steps of:
measuring a first signal power of a received signal that was received from a base station and then underwent fast Fourier transform (FFT);
generating a first range control value for matching the first signal power to an operating point of the FFT-processed original signal;
buffering the FFT-processed received signal;
measuring a second signal power of a regenerated interference signal;
comparing the first signal power with the second signal power, and generating a second range control value for controlling a gain of an output signal according to an operating point of a signal obtained by canceling the interference signal from the buffered received signal; and
controlling a gain of the interference-canceled signal using the second range control value.

33. The gain control method of claim 32, wherein the first range control value (Pref/P) is generated by dividing power (Pref) of the operating point by the first signal power (P).

34. The gain control method of claim 32, wherein the second range control value (Pref/(Pref−Pi)) is generated by dividing the signal power (Pref) of the operating point by signal power (Pref−Pi) determined by subtracting the second signal power (Pi) from the the signal power (Pref) of the operating point.
